(19) United States
(12) Patent Application Publication
(10) Pub. No.: US 2017/0047785 A1
(43) Pub. Date: Feb. 16, 2017

(54) WIRELESS POWER ENABLED ENCLOSURES FOR MOBILE DEVICES

(71) Applicant: WiTricity Corporation, Watertown, MA (US)

(72) Inventors: Karl Twelker, Somerville, MA (US); Oguz Atasoy, Watertown, MA (US); Yi Xiang Yeng, Cambridge, MA (US); Andre B. Kurs, Chestnut Hill, MA (US)

(21) Appl. No.: 15/236,784

(22) Filed: Aug. 15, 2016

Related U.S. Application Data
(60) Provisional application No. 62/204,760, filed on Aug. 13, 2015.

(51) Int. Cl. H02J 50/12; H02J 7/00; G06F 1/16; H02J 7/02; H05K 1/16

(52) U.S. Cl. CPC H02J 50/12; H02J 7/025; H05K 1/165; G06F 1/1633; H02J 7/0042

(57) ABSTRACT

The disclosure features mobile electronic devices configured to be wirelessly charged, the devices featuring a receiver resonator configured to capture oscillating magnetic flux, the receiver resonator including: a conductive material layer defining an aperture and a slit extending from the aperture to an outer edge of the conductive material layer, where the conductive material layer forms a back cover of the mobile electronic device, and an inductor having first and second conductor traces, the first trace coupled to a first portion of the conductive material layer adjacent to a first side of the slit and the second trace coupled to a second portion of the conductive material layer adjacent to a second side of the slit.

### CROSS-REFERENCE TO RELATED APPLICATIONS

This application incorporates herein by reference and claims priority to U.S. Provisional Patent Application No. 62/204,760 filed Aug. 13, 2015 and entitled “Wireless power enabled enclosures for mobile devices”.

### TECHNICAL FIELD

The field of this invention relates to wireless power transfer.

### BACKGROUND

Energy can be transferred from a power source to receiving device using a variety of known techniques such as radiative (far-field) techniques. For example, radiative techniques using low-directionality antennas can transfer a small portion of the supplied radiated power, namely, that portion in the direction of, and overlapping with, the receiving device used for pick up. In this example, most of the energy is radiated away in all the other directions than the direction of the receiving device, and typically the transferred energy is insufficient to power or charge the receiving device. In another example of radiative techniques, directional antennas are used to confine and preferentially direct the radiated energy towards the receiving device. In this case, an uninterruptible line-of-sight and potentially complicated tracking and steering mechanisms are used.

Another approach is to use non-radiative (near-field) techniques. For example, techniques known as traditional induction schemes do not (intentionally) radiate power, but uses an oscillating current passing through a primary coil, to generate an oscillating magnetic near-field that induces currents in a near-by receiving or secondary coil. Traditional induction schemes can transfer modest to large amounts of power over very short distances. In these schemes, the offset tolerance offset tolerances between the power source and the receiving device are very small. Electric transformers and proximity chargers are examples using the traditional induction schemes.

### SUMMARY

In a first aspect, the disclosure features mobile electronic devices configured to be wirelessly charged. The device can include a receiver resonator configured to capture oscillating magnetic flux. The receiver resonator can include a conductive material layer defining an aperture and a slit extending from the aperture to an outer edge of the conductive material layer. The conductive material layer forms a back cover of the mobile electronic device. The receiver resonator can include an inductor having first and second conductor traces. The first trace can be coupled to a first portion of the conductive material layer adjacent to a first side of the slit and the second trace can be coupled to a second portion of the conductive material layer adjacent to a second side of the slit.

Embodiments of the modules can include any one or more of the following features.

The conductive material layer can be substantially in a first plane and the inductor is substantially in a second plane and the first and second planes can be substantially parallel to one another. The inductor can be a coil printed on a circuit board.

The device can include a magnetic material layer in a third plane parallel to the second plane. The magnetic material layer can be positioned opposite the conductive material layer with respect to the inductor. The first edge of the magnetic material layer can extend to a first portion of the outer edge of the conductive material layer. The magnetic material can be configured to cover the slit. The second edge of the magnetic material layer can extend to a second portion of the outer edge of the conductive material layer.

The device can include a metallic material layer in a fourth plane parallel to the third plane. The metallic material layer can be configured to cover a battery of the mobile electronic device.

Embodiments of the devices can also include any of the other features disclosed herein, including features disclosed in connection with different embodiments, in any combination as appropriate.

In another aspect, the disclosure features methods including defining an aperture in a conductive material layer, defining a slit extending from the aperture to an outer edge of the conductive material layer, and coupling a first trace of an inductor to a first portion of the conductive material layer adjacent to a first side of the slit and a second trace to a second portion of the conductive material layer adjacent to a second side of the slit.

Embodiments of the methods can also include any of the other features disclosed herein, including features disclosed in connection with different embodiments, in any combination as appropriate.

In another aspect, the disclosure features wireless power systems includes a transmitter that includes a transmitter resonator coil in a first plane. When the resonator coil is driven with an oscillating current, the resonator coil generates an oscillating magnetic field with a dipole moment orthogonal to the first plane. The systems can include a receiver including a receiver resonator configured to capture oscillating magnetic flux. The receiver resonator can include a conductive material layer defining an aperture and a slit extending from the aperture to an outer edge of the conductive material layer. The conductive material layer can form a back cover of the mobile electronic device. The receiver resonator can include an inductor having first and second conductor traces. The first trace can be coupled to a first portion of the conductive material layer adjacent to a first side of the slit and the second trace can be coupled to a second portion of the conductive material layer adjacent to a second side of the slit.

Embodiments of the systems can also include any of the other features disclosed herein, including features disclosed in connection with different embodiments, in any combination as appropriate.

In another aspect, the disclosure features receiver resonators configured to capture oscillating magnetic flux. The receiver resonator can include a conductive material layer defining an aperture and a slit extending from the aperture to an outer edge of the conductive material layer. The conductive material layer can form a back cover of the mobile electronic device. The receiver resonator can include an inductor having first and second conductor traces. The first trace can be coupled to a first portion of the conductive material layer adjacent to a first side of the slit and the second trace can be coupled to a second portion of the conductive material layer adjacent to a second side of the slit.

Embodiments of the receiver resonators can also include any of the other features disclosed herein, including features disclosed in connection with different embodiments, in any combination as appropriate.

### BRIEF DESCRIPTION OF THE DRAWINGS

FIG. 1 shows an exemplary embodiment of a wireless power source transferring power to a wirelessly chargeable mobile electronic device having a metallic cover via an oscillating magnetic field.

FIG. 2 shows an exemplary embodiment of a wireless power transfer system.

FIG. 3 shows an exploded view of an exemplary embodiment of a wirelessly chargeable device, such as a phone.

FIGS. 4A-4B show exemplary embodiments of coupled components to an enclosure for a wirelessly chargeable device, such as a phone.

FIG. 5A shows an exploded view of an exemplary embodiment of a wirelessly chargeable mobile device.

FIG. 5B shows a cross-sectional view of an exemplary embodiment of a wirelessly chargeable mobile device.

FIG. 6A shows an exemplary embodiment of an enclosure for a wirelessly chargeable mobile device, such as a laptop.

FIGS. 6B and 6C show exemplary embodiments of the enclosure of FIG. 6A coupled to an inductor.

FIGS. 7A and 7B show an exemplary embodiment of an enclosure having two or more pieces for the enclosure of a wirelessly chargeable mobile device.

FIG. 8A shows an exploded view of an exemplary embodiment of a wirelessly chargeable device, such as a laptop.

FIG. 8B shows cross-sectional view of an exemplary embodiment of a wirelessly chargeable mobile device

FIGS. 9A-9C show exemplary embodiments of a magnetic material layer positioned relative to the enclosure of FIG. 6A.

FIG. 10A shows an exemplary embodiment of an enclosure for a wirelessly chargeable mobile device, such a laptop.

FIG. 10B shows an exemplary embodiment of the enclosure of FIG. 10A coupled to an inductor.

FIG. 10C shows an exemplary embodiment of a magnetic material layer positioned relative to the enclosure of FIG. 10A.

### DETAILED DESCRIPTION

Enclosures for mobile electronic devices may utilize metallic materials for both mechanical durability and aesthetic quality. Some metallic materials such as aluminum have the advantage of being both strong and lightweight. For example, many smartphones, tablets, and laptops can be made both thin and ruggedized by including these materials in its construction. In practical implementations, an electronic device can be configured to receive wireless power by installing a wireless power receiver within the enclosure of the electronic device, such as within the back cover of a smartphone or bottom chassis of a laptop. However, a metallic enclosure architecture can make a difference in the efficiency of wireless power transfer. In some cases, little to no power can be received by a receiver that is entirely blocked by metallic or conductive materials. Described herein are exemplary systems and methods to enable electronic devices to successfully receive wireless power within acceptable efficiency ranges, such as greater than 50%, 60%, 70%, or more.

Various aspects of wireless power systems are disclosed, for example, in commonly owned U.S. Patent Application Publication No. 2012/0119569 A1, U.S. Patent Application Publication No. 2013/0200721 A1, and U.S. Patent Application Publication 2013/0033118 A1, U.S. Patent Application Publication 2013/0057364 A1, the entire contents of which are incorporated by reference herein.

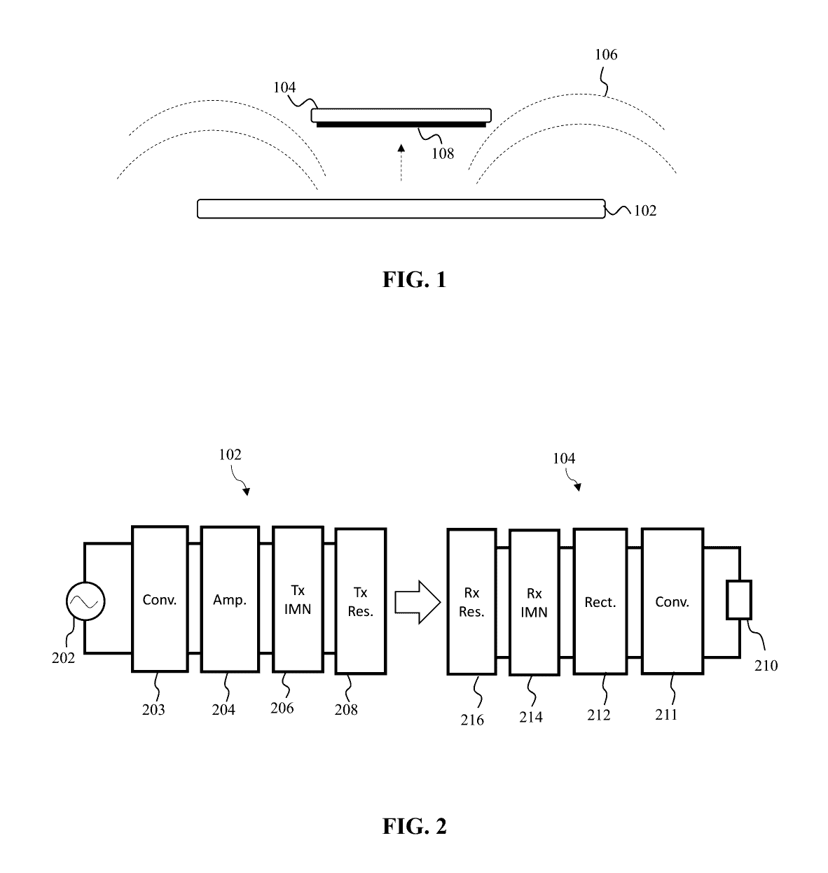

FIG. 1 shows a wireless power transfer system including a wireless power transmitter 102 configured to transfer energy to a wireless power receiver 104 via an oscillating magnetic field 106. Note that in the exemplary use case shown, the receiver 104 may be placed on or over a transmitter pad 102 for charging. In embodiments, a transmitter pad may be mounted under a surface such as a table and the receiver may rest and charge wirelessly on top of the surface. The receiver 104 can receive power through parts and/or enclosures made of conductive material 108, such as metal or alloys. In embodiments, some or all of the housing of the receiver can be made of conductive material. For example, the back cover and/or housing of a smartphone, tablet, or personal computer having a wireless power receiver may be primarily made of aluminum, aluminum alloy, magnesium, copper, or other alloy.

FIG. 2 shows a schematic of an exemplary wireless power system. The transmitter side 102 can include a power supply 202 (such as AC mains, battery, solar panel, and the like), an AC/DC converter 203 (such as a buck, boost, buck-boost, etc.), an amplifier 204 (such an RF inverter), an impedance matching network (Tx IMN) 206, a transmitter resonator 208. The transmitter resonator 208 includes one or more transmitter resonator coils coupled, in parallel or in series, to one or more capacitors. The receiver side 104 can include a load 210 (such as a battery of a mobile electronic device), a DC/DC converter 211, a rectifier 212, an impedance matching network (Rx IMN) 214, and a receiver resonator 216. The receiver resonator 216 includes one or more receiver resonator coils coupled, in parallel or in series, to one or more capacitors.

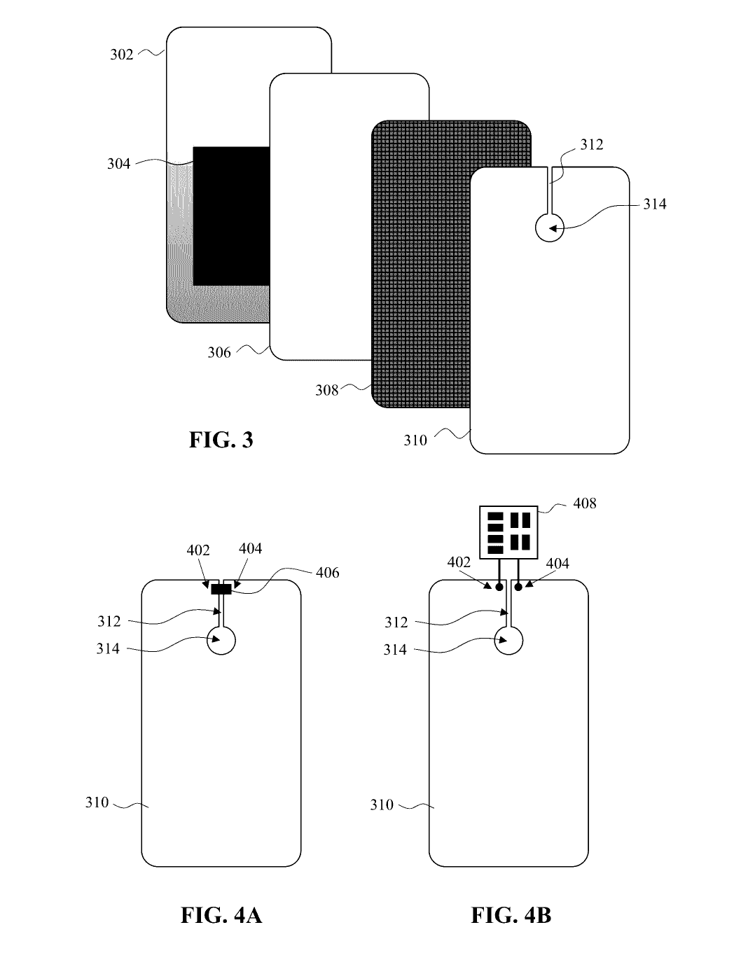

In exemplary embodiments, a coil of the receiver resonator 216 can be used as the enclosure of an electronic device, such as a smartphone or laptop. For example, the back enclosure of the electronic device can be shaped to capture magnetic flux from a wireless power transmitter. FIG. 3 shows an exemplary embodiment of a wirelessly chargeable mobile device. The device includes the body 302 of the mobile electronic device (such as a smartphone) connected to a battery 304, a layer of conductive material 306 (such as aluminum, copper, magnesium, and the like) to provide a shield between the body 302 and magnetic flux in the layer of magnetic material 308 (such as ferrite), and an outer layer 310 made of conductive material. The magnetic material 308 can act as a shield between the receiver resonator and the body 302 plus layer 306 and can act as a guide and/or return path for magnetic flux captured by the receiver resonator. The outer layer 310 of conductor forms both the back of the mobile device and the receiver resonator coil. The shape of the outer layer 310 can be formed as a “one-turn” inductor of the receiver resonator coil. The outer layer 310 includes a slit 312 from an outer edge of the outer layer 310 to an aperture 314 defined in the outer layer 310. This shape allows for an oscillating magnetic field to be captured by the resonator coil. In embodiments, a module may include the outer layer 310, magnetic material layer 308, and shield 306. This module may be manufactured separately and mounted onto the mobile device.

As shown in FIG. 4A, the two edges 402, 404 created by the slit 312 can be coupled to one or more capacitors 406 and/or, as shown in FIG. 4B, a circuit board 408. The views shown in FIG. 4A and FIG. 4B are on the inside of the outer layer (and therefore, opposite side of the view shown in FIG. 3). In embodiments, the capacitor 406 can be connected to the two edges 402, 404 close to the slit 312. For example, the capacitor 406 can be connected across the slit 312 as shown in FIG. 4A, or can connect to the two edges 402, 404 adjacent to the slit 312 (via a circuit board 408) as shown in FIG. 4B. The circuit board 408 can include the one or more capacitors, an impedance matching network 214, a rectifier 212, a DC-to-DC converter 211, etc. The circuit board 408 can be coupled to the outer layer 310 by wires and can be positioned between the outer layer 310 and the body 302, for example, by folding or positioning the circuit board 408 behind the outer layer 310. In embodiments, the conductive layer 306 and magnetic material layer 308 can be positioned between the outer layer 310 and the electronics board 408. In other embodiments, the conductive layer 306 and magnetic material layer 308 can be positioned between the circuit board 408 and the body 302.

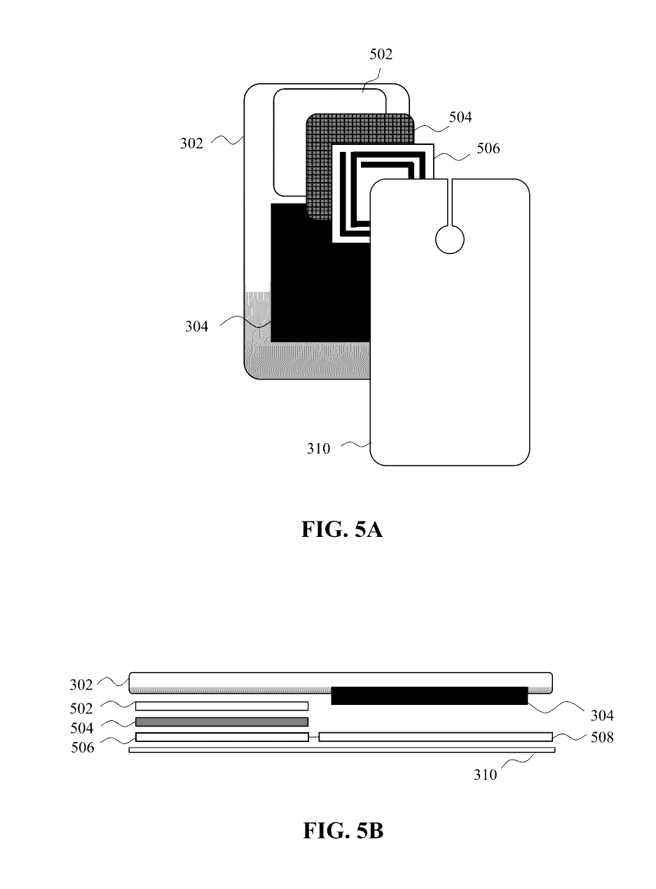

In embodiments, the voltage induced on the “one-turn resonator coil” may be too low to use to power a load or battery of the mobile electronic device. Additional inductor turns can be coupled to the one-turn coil to increase inductance, quality factor, and/or induced voltage. FIG. 5A shows an exemplary embodiment of a wirelessly chargeable mobile device. The device includes the body 302 connected to a battery 304, a layer of conductive material 502, a layer of magnetic material 504, an inductor 506, and an outer layer 310 made of conductive material. The inductor 506 can be coupled, inductively or directly by wire, to the “one-turn” coil created by the outer layer 310 of conductive material. Note that in some embodiments, the amount of conductive material 502 and magnetic material 504 can be reduced in area to cover the inductor 506 as compared to that shown in FIG. 3. In embodiments, the inductor 506 can be a coil on a printed circuit board or made of Litz wire. The outer layer 310 coupled to at least one capacitor may be used as a repeater resonator to a receiver resonator coil 506 positioned behind the outer layer 310. FIG. 5B shows a cross-sectional view of an exemplary embodiment of a wirelessly chargeable mobile device. The mobile device includes the body 302 connected to a battery 304, a layer of conductive material 502, a layer of magnetic material 504, an inductor 506, and an outer layer 310 comprising conductive material. Further, a circuit board 508 is included between the outer layer 310 and the body of the mobile device 302; the circuit board 508 can include the one or more capacitors, an impedance matching network 214, a rectifier 212, a DC-to-DC converter 211, etc. In embodiments, a module may include the outer layer 310, inductor 506, magnetic material layer 308, and shield 306. This module may be manufactured separately and mounted onto the mobile device.

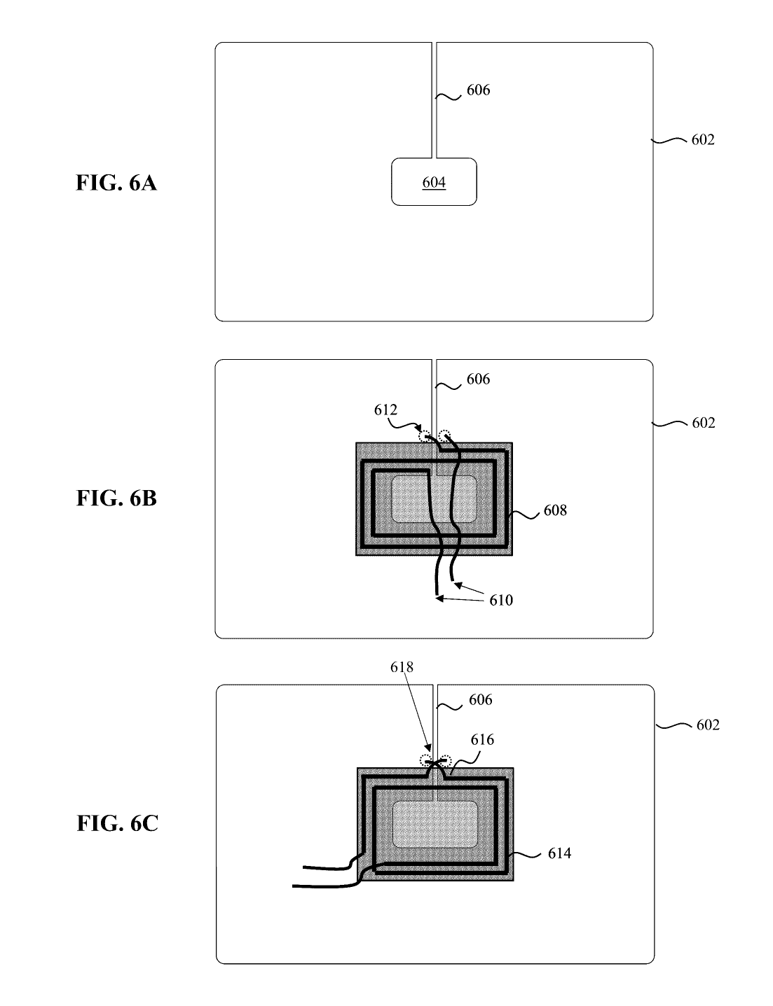

FIG. 6A shows an exemplary embodiment of an outer layer 602 of conductive material for a mobile electronic device such as a tablet, laptop, and the like. This outer layer 602 can be attached to a back of a laptop and have a dual-role as both the enclosure and inductor for capturing magnetic flux from a wireless power transmitter. The outer layer 602 of conductive material has an aperture 604 in its approximate center. Additionally, a slit 606 runs from one edge of the outer layer 602 to the aperture 604, which can create a “one-turn” coil as part of a receiver resonator. FIG. 6B shows an additional coil 608 coupled to the outer layer 602. Leads 610 can then be connected to at least one capacitor. The “one-turn” coil 602 can be coupled to the inductor 608 such that the magnetic field from any one segment of the overall resonator coil (“one-turn” coil 602 plus inductor 608) does not cancel with another segment of the overall resonator coil. In other words, the current induced in the outer layer 602 and coil 608 flows in the same direction. Thus, FIG. 6B shows the “one-turn” coil 602 turn clockwise and connect with inductor 608 at solder point 612 and then continue clockwise through the inductor 608. FIG. 6C shows an exemplary embodiment of coupling the “one-turn” coil 602 into the inductor 614 such that the “one-turn” coil is part of the inductor turn 616. In embodiments, the coil 608 can be any size within the area of the outer layer 602. However, the amount of magnetic flux that can be captured by the coil 608 can be limited by the size of aperture 604. In embodiments, the size of the aperture 604 can be similarly sized to the innermost loop of the inductor. One advantage of a larger coil may be the ability to fit more turns, which may increase the quality factor of the overall resonator coil. In embodiments, the quality factor of the overall resonator coil can be greater than 20, 50, 75, 100, 200, etc. In embodiments, the “one-turn” coil 602 coupled to inductor 608 can increase coupling between the receiver resonator and the transmitter resonator. For example, coupling can be increased by at least 10%, 20%, 30% or more. Note that in both embodiments shown in FIG. 6B and FIG. 6C, the current path created by the outer layer 602 is in series with the current path of the coil 608 and 614 respectively. Note also that in FIG. 6C, a cross-over 618 in the connections to the outer layer is formed to maintain the directionality of the current path.

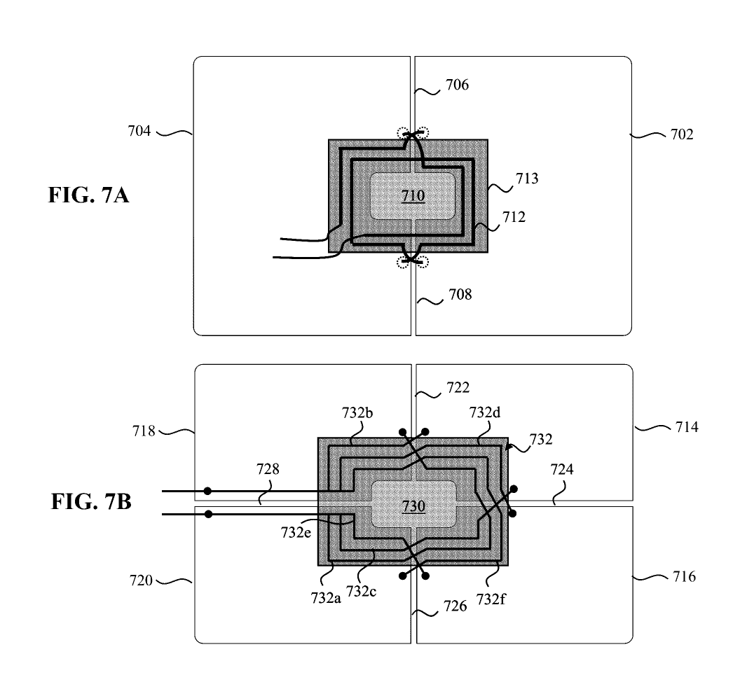

FIG. 7A shows an exemplary embodiment of an outer layer having two pieces 702, 704 of conductive material for a mobile device such as a tablet, laptop, and the like. These two pieces 702, 704 of conductive material may be created by two slits 706 and 708 running from the outer edges of the outer layer to the aperture 710. The two pieces are coupled to the inductor 712 such that the current paths created by each piece 702, 704 are in series with current path of the inductor 712. Note that the inductor 712 can be printed on a circuit board (PCB) 713. FIG. 7B shows an exemplary embodiment of an outer layer having four pieces 714, 716, 718, and 720 of conductive material. The four pieces can be defined by four slits 722, 724, 726, and 728 running from the outer edges of the outer layer to the aperture 730. The four pieces 714, 716, 718, and 720 are coupled to the inductor 732 such that the current paths created by a piece plus a loop of the inductor coil 732 are in parallel with current paths of the other pieces plus turns of the inductor 732. For example, current path A includes piece 718 connected to loop 732a of inductor 732; current path B includes piece 714 connected to loops 732b and 732c; current path C includes piece 716 connected to loops 732d and 732e; and current path D includes pieces 720 connected to loop 732f. Each of these current paths are in parallel with each other.

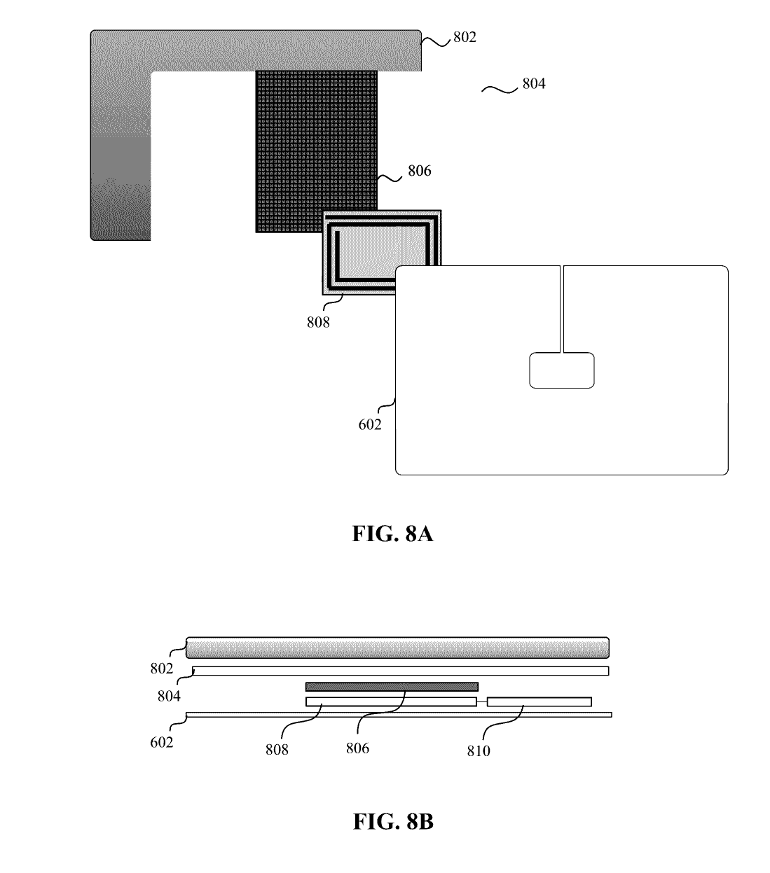

FIG. 8A shows an exemplary embodiment of a wirelessly chargeable mobile device. The device includes the body 802, a layer of conductive material 804, a layer of magnetic material 806, an inductor 808, and an outer layer 602 made of conductive material. FIG. 8B shows cross-sectional view of an exemplary embodiment of a wirelessly chargeable mobile device including the materials described above for FIG. 8A. The device also includes a circuit board 810 connected to the inductor 808.

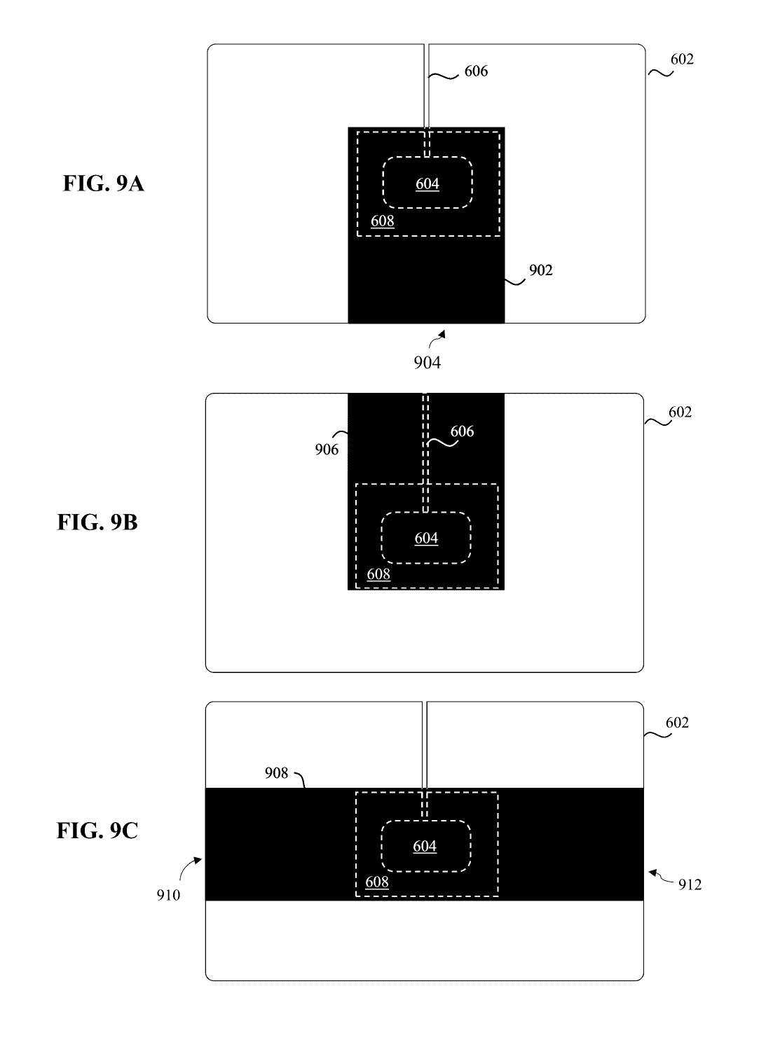

FIGS. 9A-9C show exemplary embodiments of a layer of magnetic material 902 positioned over inductor 608 on the outer layer 602. In FIG. 9A, the layer of magnetic material is positioned over the inductor 608 and aperture 604 and extended to an outer edge 904. This position of the magnetic material 902 provides a return or “escape” path for the magnetic field lines from the transmitter. Providing a return path for the field lines decreases losses in the metallic surfaces in the mobile device, thus preventing a decrease in efficiency. For example, losses in the metallic surfaces can be due to induced eddy currents. FIG. 9B shows a layer of magnetic material 906 positioned over the inductor 608 and aperture 604 and extended over the slit 606. This has the similar effect of providing a return path for the magnetic field lines. In embodiments, the magnetic material can be ferrite, for example, having an approximate thickness of 0.3 mm, 0.5 mm, 0.8 mm, 1.1 mm, or more. FIG. 9C shows a layer of magnetic material 908 positioned over the inductor 608 and extending two outer edges 910, 912 of the outer layer 602. Because the layer of magnetic material 908 extends to two outer edges 910, 912, there is an increased area for a return path for magnetic field lines.

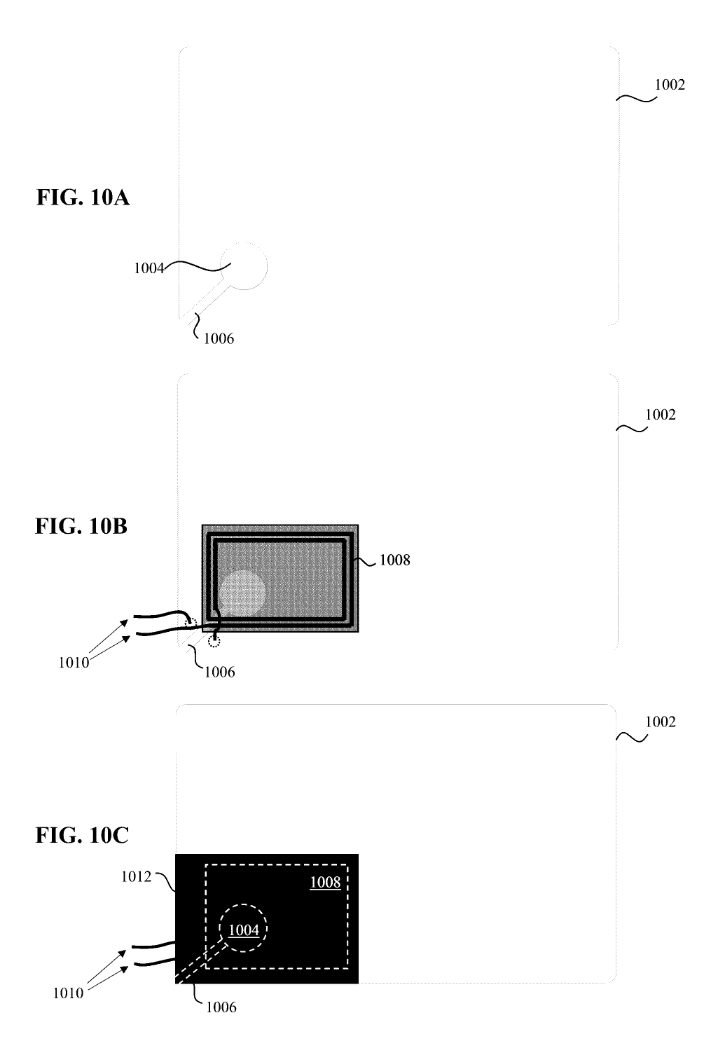

FIG. 10A shows an exemplary embodiment of an outer layer 1002 of conductive material for a mobile electronic device such as a tablet, laptop, and the like. The outer layer 1002 includes an aperture near a corner. Slit 1006 extends from the outer edge of the outer layer 1002 to the aperture. This effectively creates a “one-turn” coil. In embodiments, placing the aperture and slit in a corner of the outer layer 1002 can change the inductance of the “one-turn” coil as compared to an aperture and slit placed as shown in FIG. 6A. FIG. 10B shows an exemplary embodiment of an outer layer 1002 coupled to an inductor 1008 positioned over aperture 1004. FIG. 10C shows an exemplary embodiment of a layer of magnetic material 1012 positioned over inductor 1008 on the outer layer 1002. This position of the magnetic material 1012 provides a return path for magnetic field lines from the source. Because magnetic material 1012 is positioned in a corner, it can provide that return path on more than one outer edge of the outer layer 1002. Furthermore, this position may allow the use of less magnetic material 1012 because of its close proximity to the edges at the corner. Less magnetic material can mean decreased overall weight and cost.

In exemplary embodiments, the receiver resonator coil, while thin, can be maximized in the area of the back of the mobile device, keeping in mind that certain areas such as a camera lens or speaker should not be covered.

In exemplary embodiments, a logo can be etched into the outer layer of conductive material.

In exemplary embodiments, the outer layer only covers a portion of the back surface of the mobile electronic device. Other materials, such as glass, plastics, wood/plant materials, and leather may be used together with the metal back enclosure to form the back cover of the mobile electronic device.

In exemplary embodiments, the resonator coil under the outer layer can be used as a dual use antenna. For example, the same coil can be used as a wireless power transfer coil at 6.78 MHz and as a coil for communication at 13.56 MHz. In embodiments, the wireless power transfer coil can transfer power at other frequencies such as 100 kHz-250 kHz.

While the disclosed techniques have been described in connection with certain preferred embodiments, other embodiments will be understood by one of ordinary skill in the art and are intended to fall within the scope of this disclosure. For example, designs, methods, configurations of components, etc. related to transmitting wireless power have been described above along with various specific applications and examples thereof. Those skilled in the art will appreciate where the designs, components, configurations or components described herein can be used in combination, or interchangeably, and that the above description does not limit such interchangeability or combination of components to only that which is described herein.

All documents referenced herein are hereby incorporated by reference.

What is claimed is:

1. A mobile electronic device configured to be wirelessly charged, the device comprising:
a receiver resonator configured to capture oscillating magnetic flux, the receiver resonator comprising:
a conductive material layer defining an aperture and a slit extending from the aperture to an outer edge of the conductive material layer, wherein the conductive material layer forms a back cover of the mobile electronic device; and
an inductor, having first and second conductor traces, the first trace coupled to a first portion of the conductive material layer adjacent to a first side of the slit and the second trace coupled to a second portion of the conductive material layer adjacent to a second side of the slit.

2. The device of claim 1 wherein the conductive material layer is substantially in a first plane and the inductor is substantially in a second plane and wherein the first and second planes are substantially parallel to one another.

3. The device of claim 2 further comprising a magnetic material layer in a third plane parallel to the second plane, wherein the magnetic material layer is positioned opposite the conductive material layer with respect to the inductor.

4. The device of claim 3 wherein a first edge of the magnetic material layer extends to a first portion of the outer edge of the conductive material layer.

5. The device of claim 4 wherein the magnetic material is configured to cover the slit.

6. The device of claim 4 wherein a second edge of the magnetic material layer extends to a second portion of the outer edge of the conductive material layer.

7. The device of claim 3 further comprising a metallic material layer in a fourth plane parallel to the third plane.

8. The device of claim 7 wherein the metallic material layer is configured to cover a battery of the mobile electronic device.

9. The device of claim 1 wherein the inductor is a coil printed on a circuit board.

10. A method comprising:
defining an aperture in a conductive material layer;
defining a slit extending from the aperture to an outer edge of the conductive material layer; and
coupling a first trace of an inductor to a first portion of the conductive material layer adjacent to a first side of the slit and a second trace to a second portion of the conductive material layer adjacent to a second side of the slit.

11. A wireless power system comprising:
a transmitter comprising a resonator coil in a first plane, wherein when the resonator coil is driven with an oscillating current, the resonator coil generates an oscillating magnetic field with a dipole moment orthogonal to the first plane;
a receiver comprising a receiver resonator configured to capture oscillating magnetic flux, the receiver resonator comprising:
a conductive material layer defining an aperture and a slit extending from the aperture to an outer edge of the conductive material layer, wherein the conductive material layer forms a back cover of the mobile electronic device; and
an inductor, having first and second conductor traces, the first trace coupled to a first portion of the conductive material layer adjacent to a first side of the slit and the second trace coupled to a second portion of the conductive material layer adjacent to a second side of the slit.

12. A receiver resonator configured to capture oscillating magnetic flux, the receiver resonator comprising:
a conductive material layer defining an aperture and a slit extending from the aperture to an outer edge of the conductive material layer, wherein the conductive material layer forms a back cover of the mobile electronic device; and
an inductor, having first and second conductor traces, the first trace coupled to a first portion of the conductive material layer adjacent to a first side of the slit and the second trace coupled to a second portion of the conductive material layer adjacent to a second side of the slit.
